(19) United States
(12) Patent Application Publication
(10) Pub. No.: US 2025/0314803 A1
(43) Pub. Date: Oct. 9, 2025

(54) METHOD FOR CONDUCTING A CARBON DIOXIDE INJECTIVITY TEST

(71) Applicant: Schlumberger Technology Corporation, Sugar Land, TX (US)

(72) Inventors: Jiankun Yang, Beijing (CN); Li Chen, Beijing (CN); Adriaan Gisolf, Bucharest (RO); Francois-Xavier Dubost, Paris (FR); Hadrien Dumont, Paris (FR); Morten Kristensen, Lysaker (NO)

(21) Appl. No.: 19/042,710

(22) Filed: Jan. 31, 2025

Related U.S. Application Data
(60) Provisional application No. 63/627,532, filed on Jan. 31, 2024.

(51) Int. Cl. G01V 20/00; E21B 41/00; E21B 49/00; G06F 30/28

(52) U.S. Cl. CPC G01V 20/00; E21B 41/0064; E21B 49/008; G06F 30/28

(57) ABSTRACT

A method comprising validating a carbon dioxide injection operation plan at a carbon dioxide injection site, which comprises creating a first simulation model to simulate flow from the wellhead to a downhole environment and creating a second simulation model to simulate flow dynamics in a reservoir. The method further comprises conducting a carbon dioxide injection test operation based on the carbon dioxide injection plan at the carbon dioxide injection site and monitoring the carbon dioxide injection operation, which comprises measuring real-time data from the wellhead and the downhole, comparing the real-time data with the first simulation model, identifying risks from the comparison between the collected data in the first simulation model, and adjusting the carbon dioxide injection operation and based on the identified risks.

### CROSS-REFERENCE TO RELATED APPLICATIONS

The present application claims priority to U.S. Provisional Application 63/627,532 dated Jan. 31, 2024, the entirety of which is incorporated by reference.

### FIELD OF THE DISCLOSURE

Aspects of the disclosure relate to carbon dioxide injectivity. More specifically, aspects of the disclosure relate to performing carbon dioxide injectivity tests into geological stratum.

### BACKGROUND

Hydrocarbons are used in many forms by society, playing a crucial role in various sectors including transportation, energy production, and manufacturing. Large hydrocarbon fields are becoming scarce, posing significant challenges to the energy industry. The depletion of easily accessible hydrocarbon reserves means that the remaining fields are often more complex and difficult to develop.

The remaining hydrocarbon fields present multiple challenges for development. Factors such as field depth, location, high temperatures, and high pressures all contribute to the complexity. Deep-sea fields, for instance, require advanced technology and significant investment to extract hydrocarbons. Similarly, fields located in politically unstable regions pose logistical and security challenges. The high temperatures and pressures encountered in some fields necessitate specialized equipment and expertise, further driving up costs and complicating extraction processes.

The use of fossil fuels is a major source of greenhouse gases, which are widely believed to contribute to global warming. The combustion of hydrocarbons releases carbon dioxide and other pollutants into the atmosphere, exacerbating climate change. This has led to growing concerns about the environmental impact of continued fossil fuel use and has spurred efforts to find alternative energy sources and mitigate the effects of greenhouse gas emissions.

Carbon dioxide sequestration has emerged as a critical strategy for mitigating the environmental impact of fossil fuel use. By capturing and storing carbon dioxide emissions, sequestration seeks to reduce the amount of greenhouse gases released into the atmosphere. Conventional systems for carbon dioxide sequestration are limited in their capacity, allowing for only small-scale sequestration. This restricts their effectiveness in addressing the vast quantities of carbon dioxide emitted globally.

The laws of supply and demand have a profound influence on the price of hydrocarbons and the cost of related technologies. As global demand for energy continues to rise, the development of efficient and scalable carbon sequestration methods is expected to become a major economic driver. Future expectations point to an increasing emphasis on developing technologies that can effectively capture and store carbon dioxide, driven by both regulatory pressures and market forces.

While carbon sequestration offers significant environmental benefits, it also presents several drawbacks. One major issue is the presence of errors in the analysis of data related to the variation of geological fields. These errors can arise from factors such as hydrate formation or the breakdown of geological formations, leading to inaccurate assessments and potentially compromising the effectiveness of sequestration efforts.

Another significant drawback of carbon sequestration is related to worker safety. In certain circumstances, worker safety may be compromised due to incorrect analysis of a carbon sequestration project. The high pressures and temperatures involved in carbon dioxide injection processes, along with the potential for leaks and other hazards, pose serious risks to personnel working on these projects.

Additionally, existing conventional technologies for carbon sequestration are often time-consuming to perform. The complex procedures and advanced equipment required can lead to lengthy project timelines, delaying the implementation of sequestration measures and increasing costs.

There is a need to provide a more economical way to develop carbon sequestration projects compared to conventional technologies. Innovations that reduce costs while maintaining or improving the effectiveness of carbon dioxide capture and storage are essential for making sequestration a viable option on a large scale.

There is a need to provide additional worker safety compared to conventional technologies. Ensuring the safety of personnel involved in carbon sequestration projects is paramount, and advancements in technology and procedures must prioritize the well-being of workers.

There is a need to provide solutions to the drawbacks of the conventional carbon sequestration and carbon dioxide injectivity tests. Addressing issues such as data analysis errors, worker safety, and project timelines is crucial for the successful implementation of carbon sequestration initiatives. By overcoming these challenges, it will be possible to leverage carbon sequestration as a key strategy in mitigating the environmental impact of fossil fuel use and combating global warming.

There is a need to provide an apparatus and methods that are easier to operate than conventional apparatus and methods.

There is a further need to provide apparatus and methods that do not have the drawbacks discussed above.

There is a still further need to reduce economic costs associated with operations and apparatus described above with conventional tools and analysis.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are; therefore, not to be considered limiting of its scope, for the disclosure may admit to other equally effective embodiments without specific recitation. Accordingly, the following summary provides just a few aspects of the description and should not be used to limit the described embodiments to a single concept.

In one example embodiment, a method is disclosed. The method may comprise validating a carbon dioxide injection operation plan at an injection site. The method may further comprise creating a first simulation model to simulate flow from a wellhead to a downhole. The method may further comprise creating a second simulation model to simulate flow dynamics in a reservoir. The method may further comprise identifying risks from the first simulation model and the second simulation model. The method may further comprise adjusting the carbon injection operation plan to mitigate the identified risk. The method may further comprise conducting a carbon dioxide injection test operation based on the carbon dioxide injection operation plan at the injection site. The method may further comprise monitoring the carbon dioxide injection test operation. The method may further comprise measuring real-time data from the wellhead and the downhole. The method may further comprise comparing the real-time data with the first simulation model. The method may further comprise identifying risks from the comparison between the collection data and the first simulation model. The method may further comprise adjusting the carbon dioxide injection operation plan to mitigate the identified risks.

In another embodiment, a method for performing a carbon dioxide injectivity test is disclosed. The method may comprise validating a carbon dioxide injection operation plan at an injection site within a geological stratum. The method may also comprise creating a first simulation model of the injection site to simulate flow from a wellhead to a downhole environment. The method may also comprise creating a second simulation model to simulate flow dynamics in a reservoir in the geological stratum. The method may also comprise identifying risks associated with the first simulation model and the second simulation model and adjusting the carbon dioxide injection operation plan to mitigate the identified risks. The method may also comprise conducing a carbon dioxide injection test operation based on the carbon dioxide injection operation plan at the injection site within the geological stratum; and monitoring the carbon dioxide injection test operation. The method may also comprise measuring real-time data from the wellhead and the downhole environment. The method may also comprise storing the real-time data in a non-volatile memory. The method may also comprise comparing the real-time data with the first simulation model. The method may also comprise identifying risks from the comparison between the collection data and the first simulation model; and adjusting the carbon dioxide injection operation plan to mitigate the identified risks.

In another example embodiment, an article of manufacture is disclosed. The article of manufacture may be configured to be read by a computing device, the article of manufacture configured with a list of instructions, the list of instructions configured to operate on the computing device, the list of instructions configured to perform a method comprising: validating a carbon dioxide injection operation plan at an injection site, comprising creating a first simulation model to simulate flow from a wellhead to a downhole. The method may also comprise creating a second simulation model to simulate flow dynamics in a reservoir. The method may also comprise identifying risks from the first simulation model and the second simulation model; and adjusting the carbon injection operation plan to mitigate the identified risk. The method may also comprise conducting a carbon dioxide injection test operation based on the carbon dioxide injection operation plan at the injection site and monitoring the carbon dioxide injection test operation. The method may also comprise measuring real-time data from the wellhead and the downhole. The method may also comprise comparing the real-time data with the first simulation model and identifying risks from the comparison between the collected data and the first simulation model. The method may also comprise adjusting the carbon dioxide injection operation plan to mitigate the identified risks.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the drawings. It is to be noted; however, that the appended drawings illustrate only typical embodiments of this disclosure and are; therefore, not to be considered limiting of its scope, for the disclosure may admit to other equally effective embodiments.

FIG. 1 is an example of a coupled simulation for a carbon dioxide injection operation plant according to one or more examples of the disclosure.

FIG. 2 is an example of hydrate formation detection using simulated data, according to one or more examples of the disclosure.

FIG. 3 is an example of a carbon dioxide phase detection using simulated data, according to one or more examples of the disclosure.

FIG. 4 is an example of a comparison between real-time data, according to one or more examples of the disclosure.

FIG. 5 is an example of carbon dioxide front visualization in a reservoir simulation, according to one or more examples of the disclosure.

FIG. 6 is a method for conducting a carbon dioxide injectivity test in accordance with one example embodiment of the disclosure.

To facilitate understanding, identical reference numerals have been used, where possible, to designate identical elements that are common to the figures (“FIGS”). It is contemplated that elements disclosed in one embodiment may be beneficially utilized on other embodiments without specific recitation.

### DETAILED DESCRIPTION

In the following, reference is made to embodiments of the disclosure. It should be understood; however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments, and advantages are merely illustrative and are not considered elements or limitations of the claims except where explicitly recited in a claim. Likewise, reference to “the disclosure” shall not be construed as a generalization of inventive subject matter disclosed herein and should not be considered to be an element or limitation of the claims except where explicitly recited in a claim.

Although the terms first, second, third, etc., may be used herein to describe various elements, components, regions, layers and/or sections, these elements, components, regions, layers and/or sections should not be limited by these terms. These terms may be only used to distinguish one element, components, region, layer or section from another region, layer, or section. Terms such as “first”, “second”, and other numerical terms, when used herein, do not imply a sequence or order unless clearly indicated by the context. Thus, a first element, component, region, layer, or section discussed herein could be termed a second element, component, region, layer, or section without departing from the teachings of the example embodiments.

When an element or layer is referred to as being “on”, “engaged to”, “connected to”, or “coupled to” another element or layer, it may be directly on, engaged, connected, coupled to the other element or layer, or interleaving elements or layers may be present. In contrast, when an element is referred to as being “directly on”, “directly engaged to”, “directly connected to”, or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood; however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

In some embodiments, methods described may be stored in a non-volatile memory. In some embodiments, the non-volatile memory may be defined as an article of manufacture. In embodiments, the non-volatile memory is configured such that the methods may contain a list of instructions that may be read by a computing device and the list of instructions performed. The list of instructions may perform calculations, illustrate graphic results on a visual device, such as a monitor, print results, or store data for further use, as non-limiting embodiments. The list of instructions may be executable in their own programming or may be executed using other programming. The list of instructions may be stored in various configurations, such as a compact disk, a floppy disk, a solid-state drive, a computer hard drive, a server, a web-oriented storage device, and a cloud-computing device or system. Embodiments of methods described may control other systems, such as machines, to perform specified functions. Operational control may be performed through additional programming and/or operation of other computing or control devices. Embodiments described may be implemented using wireless technologies to allow for computing and execution of the list of instructions from various locations. Computing may occur, for example, in various platforms, including a personal computer, a laptop computer, a computer server, a cloud-based computer, a mainframe computer, a cellular telephone and a cellular connected device.

Embodiments of the methods described may use other programming technologies to help implement the methods described. In some embodiments, machine learning programming may be used to evaluate data and provide results. In some embodiments, training datasets may be used to allow for convergence of needed results and thus using pretrained machine learning programming is considered within the scope of the disclosure. In other instances, artificial intelligence programming systems may be implemented as part of the disclosure or may be incorporated within the methods described. Such artificial intelligence systems may be used in various capacities, including results generation, error detection, problem definition and problem convergence methods. Graphical representation of results obtained by artificial intelligence systems is also considered within the scope of the disclosure.

In embodiments using machine learning and/or artificial intelligence, programming may be altered by the programming based upon instructions provided. As such, in one non-limiting embodiment, different nodal layers of evaluation may be provided for analysis. The different nodal layers provided may incorporate modification techniques to allow for accurate reading and evaluation of large datasets. The large datasets may be designated training datasets or may be actual data that is desired to be evaluated. Coefficients used for corresponding different nodal layers may be developed within the methods described or may be pre-set according to training. Such coefficients may be altered by the computer programming itself or may be designated by a computer user. As a non-limiting embodiment, if possible results from analysis disclose too many potential outcomes or results, a computer operator may be asked or may alter the analysis protocol to achieve more focused results.

In embodiments, computer code may be any programming code that lists instructions to be followed. Programming codes may include instructions provided by a computer programmer with or without assistance by computers. Programming may occur through use of a library of programs or subroutines to section programming tasks. Programming may be accomplished to run on different operating systems or may be included with internal executable files for stand-alone computer instructions.

Illustrative examples of the subject matter claimed below will now be disclosed. In the interest of clarity, not all features of an actual implementation are described in this specification. It will be appreciated that in the development of any such actual implementation, numerous implementation-specific decisions may be made to achieve the developers' specific goals, such as compliance with system-related and business-related constraints, which will vary from one implementation to another. Moreover, it will be appreciated that such a development effort, even if complex and time-consuming, would be a routine undertaking for those of ordinary skill in the art having the benefit of this disclosure.

Embodiments of the present disclosure are directed towards a method for conducting carbon dioxide injectivity test at an injection site. Aspects of the disclosure may be separated into different sections, including pre-job planning, on-job planning and post job interpretation.

### Pre-Job Planning

The pre-job planning stage, the injectivity test may be validated based on virtual simulation models from the wellhead to the reservoir. In the on-job monitoring stage, the injectivity test may be conducted at the injection site and monitored in real-time to identify operational risks. In the post-job interpretation stage, the injectivity test may be interpreted to obtain key data parameters from the injectivity test.

In one or more embodiments, the pre-job planning stage may comprise at least two types of numerical simulations of an injection site. The first simulation may be a wellbore dynamics simulation from the wellhead to the downhole injection sand face of the injection site. The second simulation may be a flow dynamics simulation of the reservoir of the injection site. These simulations thus cover the full flow dynamics from the wellhead to the reservoir of the injection site.

In one or more embodiments, the input for the first simulation may include data pertaining to the wellbore configuration, mud properties, tool configuration, and the carbon dioxide injection plan. The input for the second simulation may comprise the estimated reservoir properties.

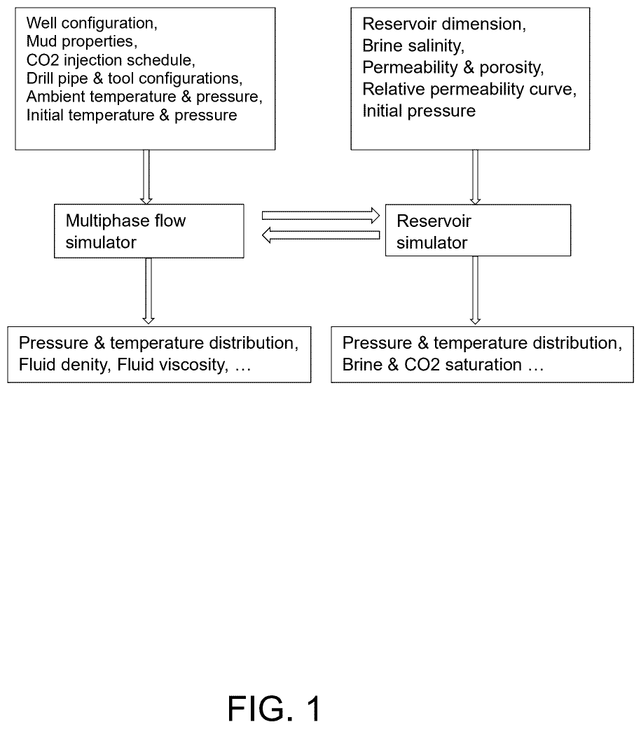

In one or more embodiments, both simulations in the pre-job planning stage may be coupled together to form a coupled simulation, as shown in the example in FIG. 1. In this embodiment, the injection pressure and flow rate determined from the first simulation may be an additional input in the second simulation, and the reservoir pressure determined from the second simulation may be an additional input in the first simulation. The simulations may also be conducted separately with simplified assumptions.

In one or more embodiments, a geomechanical model may be included if the reservoir temperature variation is expected to be drastic, as the temperature variation may cause rock deformation which, in turn, may lead to potential fracturing or permeability change.

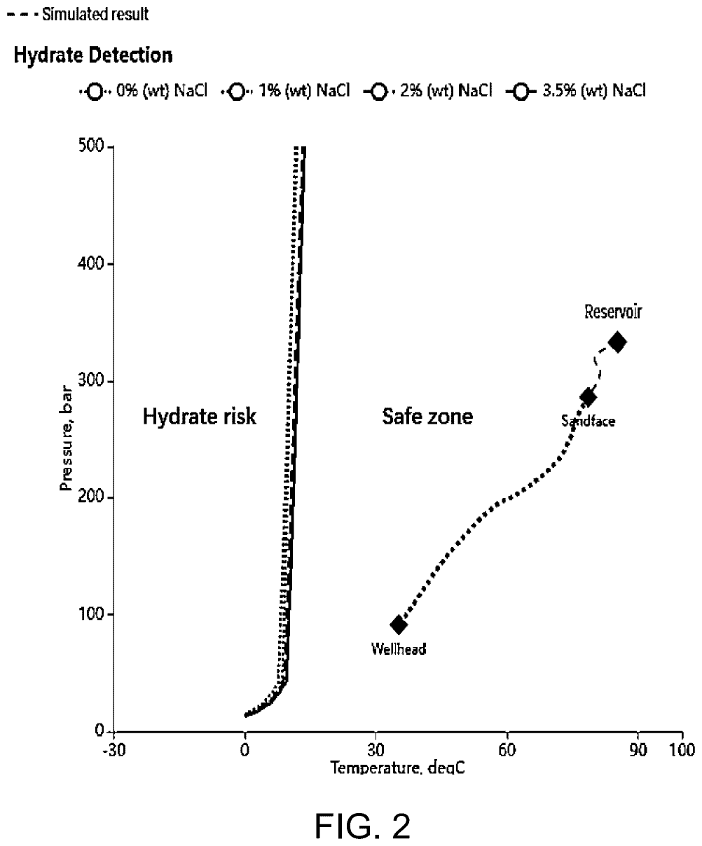

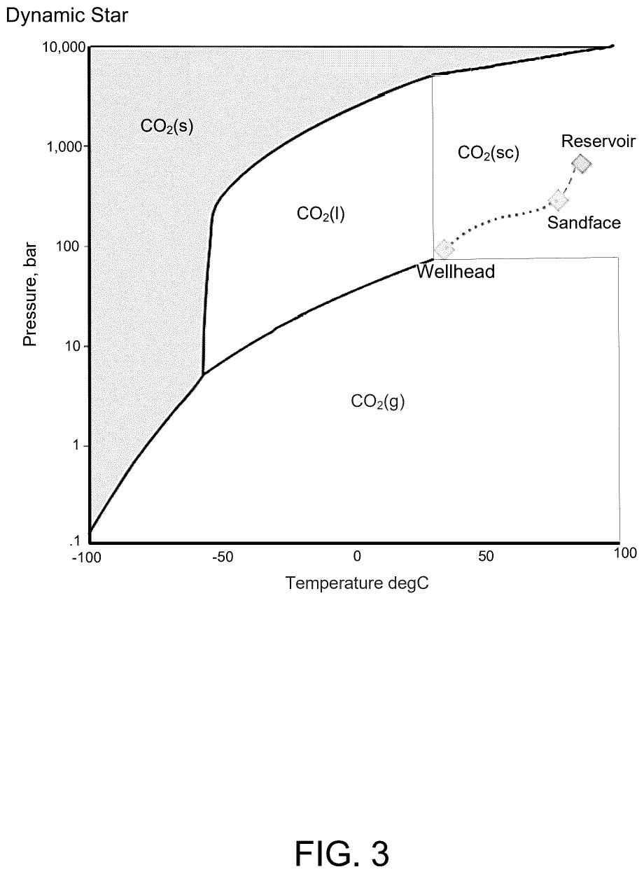

In one or more embodiments, data from the simulation models may be utilized to detect potential hydrate formation and determine carbon dioxide phase, which are crucial information for safe carbon dioxide injection operations. The simulated pressure and temperature data may be plotted against hydrate formation curves and a carbon dioxide phase diagram to visualize the information over time. An example of this is shown in FIG. 2 for hydrate formation detection, and FIG. 3 for carbon dioxide phase detection.

In one or more embodiments, the pre-job planning stage may comprise collecting simulation inputs and proposing a carbon dioxide injection plan, creating simulation models based on the simulation inputs, and running the simulations to determine potential risks in the carbon dioxide injection plan. If any potential risks are detected, the carbon dioxide injection plan may be modified accordingly, and the simulations rerun to obtain an injection plan with minimal risks. If there are no potential risks that are detected, no modifications may be made. In embodiments, if a temperature drop of the reservoir is above a threshold level, a geomechanical model may be constructed to simulate the effect of the temperature changes. The potential risks may be determined from the simulated results. If risks are detected, the injection plan may be modified and adjusted with a rerun of the simulation. Steps described above may be repeated until a safe injection plan is obtained.

### On-Job Planning

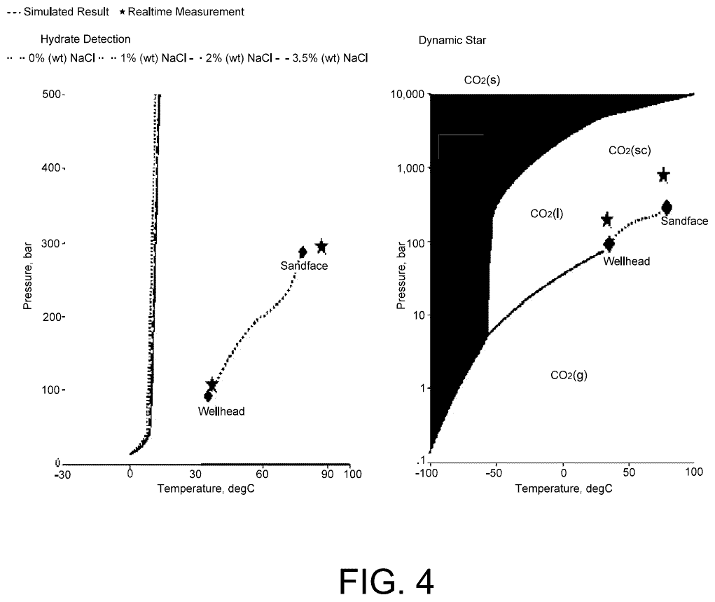

In one or more embodiments, the on-job monitoring stage may comprise measuring real-time data from the injection site during a carbon dioxide injection test operation based on the carbon dioxide injection plan. The real-time data may be measured by sensors placed at both the wellhead and the downhole of the injection site. With real-time data, the simulation model for the wellbore of the injection site may be tuned to match the real-time conditions of the injection test operation, which may enable operation optimization in real-time. Referring to FIG. 4, an example showing a comparison between the real-time data obtained at the wellhead and the simulation data is presented. The star symbols represent the real-time data and the broken lines represent the simulated data. As will be understood, monitoring of the sensors may be accomplished directly at the wellhead or at a remote location.

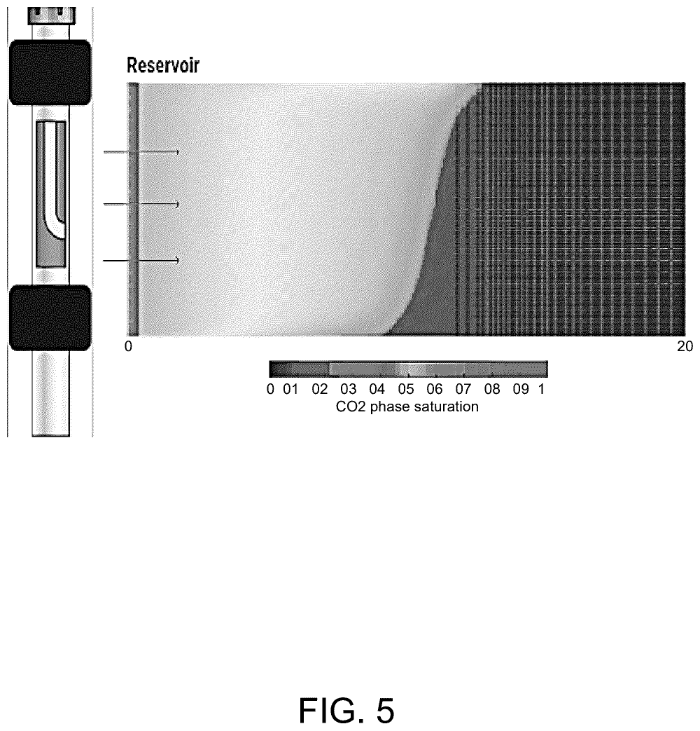

In one or more embodiments, the simulation of the reservoir of the injection site may be tuned to better represent the actual conditions of the reservoir based on data from a coupled simulation comprising both the first simulation model and the second simulation model. Data which may be used for this purpose may include carbon dioxide injection rate, bottom hole temperature, and bottom hole pressure. With the tuned reservoir simulation model, carbon dioxide flow within the reservoir can be better understood without direct measurements. For example, the front position of carbon dioxide can be visualized at a given injection time as shown in FIG. 5.

In one or more embodiments, the on-job monitoring stage may comprise: sending a drill pipe conveyed tool through to a target formation in the injection site. The on-job monitoring stage may also comprise sealing the packer and conducting the carbon dioxide injection test operation. This operation may comprise circulation, buffering fluid injection, carbon dioxide injection, etc., and measuring the surface and downhole temperature and pressure data. The operation may further comprise visualizing the real-time measured data, rerunning the wellbore dynamics simulation (the first simulation) from the pre-job planning stage to match the real-time measured data to improve prediction accuracy and identifying risks. The method may also comprise adjusting the carbon dioxide injection plan based on identified risks, and tuning the reservoir simulation model based on the real-time measured data to show a more accurate representation of carbon dioxide plume movement in the reservoir. This may be accomplished in real-time.

### Post-Job Interpretation

In one or more embodiments, the post-job interpretation stage may comprise interpreting data from the carbon dioxide injection test operation to infer key information which may be conducted using data inversion. Information that may be inferred from the carbon dioxide injection test operation may include relative permeability of carbon dioxide at different saturation, brine salinity, and other information. Key information inferred from the injection test operation may be critical as guidance for the carbon dioxide injection operation.

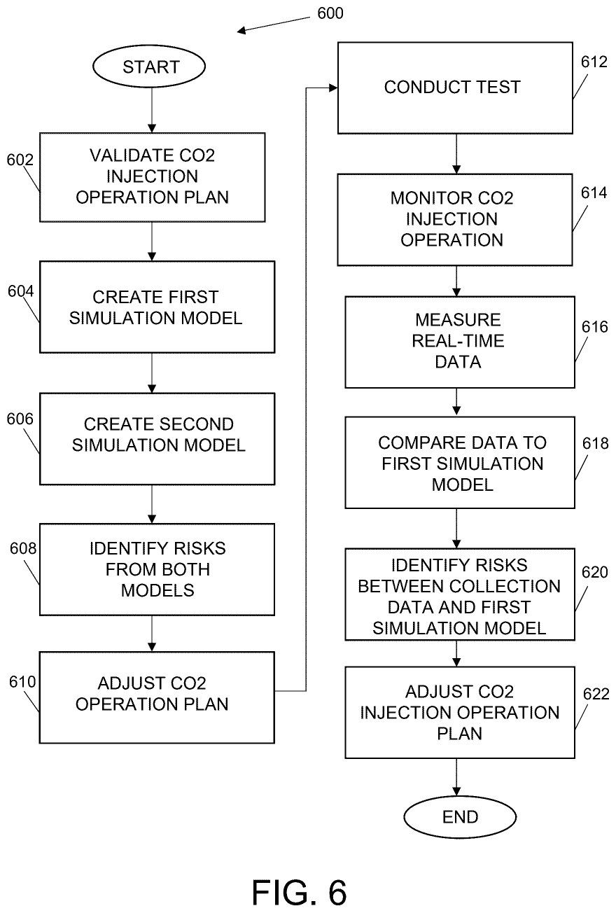

In one or more embodiments, complex models such as thermal, hydraulic, mechanical, and chemical (THMC) models may be applied to interpret data from the carbon dioxide injection operation. For example, a non-isothermal reservoir model coupled with a geomechanical model may be applied to match the measurements which provide insights on the domination mechanism of the carbon dioxide injection operation. Referring to FIG. 6, a method 600 is disclosed. The method 600 may comprise validating a carbon dioxide injection operation plan at an injection site at 602. The method may further comprise, at 604, creating a first simulation model to simulate flow from a wellhead to a downhole. The method may further comprise, at 606, creating a second simulation model to simulate flow dynamics in a reservoir. The method may further comprise, at 608, identifying risks from the first simulation model and the second simulation model. The method may further comprise, at 610, adjusting the carbon injection operation plan to mitigate the identified risk. The method may further comprise, at 612, conducting a carbon dioxide injection test operation based on the carbon dioxide injection operation plan at the injection site. The method may further comprise, at 614, monitoring the carbon dioxide injection test operation. The method may further comprise, at 616, measuring real-time data from the wellhead and the downhole. The method may further comprise, at 618, comparing the real-time data with the first simulation model. The method may further comprise, at 620, identifying risks from the comparison between the collection data and the first simulation model. The method may further comprise, at 622, adjusting the carbon dioxide injection operation plan to mitigate the identified risks. As will be understood, variations of the above may be performed. For example, data obtained may be stored in a non-volatile memory. Data may also be displayed for operator use. As will be understood, instead of using packers for sealing, other means may be used. Such non-limiting example embodiments of components that may be used include using formation testing devices. In other embodiments, different steps of the method may also be accomplished, at least in part, by use of a formation tester.

Example embodiments of the claims are recited next. The embodiments disclosed should not be considered limiting of the disclosure.

In one example embodiment, a method is disclosed. The method may comprise validating a carbon dioxide injection operation plan at an injection site. The method may further comprise creating a first simulation model to simulate flow from a wellhead to a downhole. The method may further comprise creating a second simulation model to simulate flow dynamics in a reservoir. The method may further comprise identifying risks from the first simulation model and the second simulation model. The method may further comprise adjusting the carbon injection operation plan to mitigate the identified risk. The method may further comprise conducting a carbon dioxide injection test operation based on the carbon dioxide injection operation plan at the injection site. The method may further comprise monitoring the carbon dioxide injection test operation. The method may further comprise measuring real-time data from the wellhead and the downhole. The method may further comprise comparing the real-time data with the first simulation model. The method may further comprise identifying risks from the comparison between the collection data and the first simulation model. The method may further comprise adjusting the carbon dioxide injection operation plan to mitigate the identified risks.

In another example embodiment, the method may further comprise interpreting data from the carbon dioxide injection test operation to infer key information.

In another example embodiment, the steps of validating the carbon dioxide injection operation plan may be performed wherein the steps of validating the carbon dioxide injection operation plan are repeated to obtain a final carbon dioxide injection operation plan with minimal identified risk.

In another example embodiment, the steps of monitoring the carbon dioxide injection test operation are repeated to obtain a final carbon dioxide injection operation plan with minimal identified risk.

In another example embodiment, the monitoring of the carbon dioxide injection operation further comprises tuning the second simulation model based on the measured real-time data.

In another example embodiment, the steps of modifying the first simulation model and the second simulation model based on the real-time data may be performed wherein modifying the first simulation model and the second simulation model based on the real-time data.

In another example embodiment, the validating of the carbon dioxide operation plan may be performed wherein applying a geomechanical model to the first simulation model and the second simulation model.

In another embodiment, a method for performing a carbon dioxide injectivity test is disclosed. The method may comprise validating a carbon dioxide injection operation plan at an injection site within a geological stratum. The method may also comprise creating a first simulation model of the injection site to simulate flow from a wellhead to a downhole environment. The method may also comprise creating a second simulation model to simulate flow dynamics in a reservoir in the geological stratum. The method may also comprise identifying risks associated with the first simulation model and the second simulation model and adjusting the carbon dioxide injection operation plan to mitigate the identified risks. The method may also comprise conducing a carbon dioxide injection test operation based on the carbon dioxide injection operation plan at the injection site within the geological stratum; and monitoring the carbon dioxide injection test operation. The method may also comprise measuring real-time data from the wellhead and the downhole environment. The method may also comprise storing the real-time data in a non-volatile memory. The method may also comprise comparing the real-time data with the first simulation model. The method may also comprise identifying risks from the comparison between the collection data and the first simulation model; and adjusting the carbon dioxide injection operation plan to mitigate the identified risks.

In another example embodiment, the method may further comprise interpreting data from the carbon dioxide injection test operation to infer key information.

In another example embodiment, the method may further comprise repeating the steps of validating the carbon dioxide injection operation plan to obtain a final carbon dioxide injection operation plan with a minimal identified risk.

In another example embodiment, the method may further comprise repeating the steps of monitoring the carbon dioxide injection test operation to obtain a final carbon dioxide injection operation plan with minimal identified risk.

In another example embodiment, the method may be performed wherein the monitoring of the carbon dioxide injection operation further comprises tuning the second simulation model based on the measured real-time data.

In another example embodiment, the method may be performed wherein after the comparing of the real-time data with the first simulation model and the second simulation model, further comprises modifying the first simulation model and the second simulation model based on the real-time data.

In another example embodiment, the method may be performed wherein the validating of the carbon dioxide operation plan further comprises applying a geomechanical model to the first simulation to the first simulation model and the second simulation model.

In another example embodiment, the method may further comprise displaying the adjusted carbon dioxide injection operation plan.

In another example embodiment, the method may be performed wherein at least one of the first simulation model and the second simulation model are prepared using field data of the geological stratum.

In another example embodiment, the method may further comprise stopping the carbon dioxide injection test operation when the identified risks meet a threshold.

In another example embodiment, the method may be performed wherein historical data is used to create the first simulation model.

In another example embodiment, an article of manufacture is disclosed. The article of manufacture may be configured to be read by a computing device, the article of manufacture configured with a list of instructions, the list of instructions configured to operate on the computing device, the list of instructions configured to perform a method comprising: validating a carbon dioxide injection operation plan at an injection site, comprising creating a first simulation model to simulate flow from a wellhead to a downhole. The method may also comprise creating a second simulation model to simulate flow dynamics in a reservoir. The method may also comprise identifying risks from the first simulation model and the second simulation model and adjusting the carbon injection operation plan to mitigate the identified risk. The method may also comprise conducting a carbon dioxide injection test operation based on the carbon dioxide injection operation plan at the injection site and monitoring the carbon dioxide injection test operation. The method may also comprise measuring real-time data from the wellhead and the downhole. The method may also comprise comparing the real-time data with the first simulation model and identifying risks from the comparison between the collected data and the first simulation model. The method may also comprise adjusting the carbon dioxide injection operation plan to mitigate the identified risks.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may be varied in many ways. Such variations are not to be regarded as a departure from the disclosure, and all such modifications are intended to be included within the scope of the disclosure.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

What is claimed is:

1. A method, comprising:
validating a carbon dioxide injection operation plan at an injection site, comprising:
creating a first simulation model to simulate flow from a wellhead to a downhole;
creating a second simulation model to simulate flow dynamics in a reservoir;
identifying risks from the first simulation model and the second simulation model; and
adjusting the carbon injection operation plan to mitigate the identified risk;
conducting a carbon dioxide injection test operation based on the carbon dioxide injection operation plan at the injection site;
monitoring the carbon dioxide injection test operation, comprising:
measuring real-time data from the wellhead and the downhole;
comparing the real-time data with the first simulation model; and
identifying risks from the comparison between the collection data and the first simulation model; and
adjusting the carbon dioxide injection operation plan to mitigate the identified risks.

2. The method according to claim 1, further comprising interpreting data from the carbon dioxide injection test operation to infer key information.

3. The method according to claim 1, wherein the steps of validating the carbon dioxide injection operation plan is repeated to obtain a final carbon dioxide injection operation plan with minimal identified risk.

4. The method according to claim 1, wherein the steps of monitoring the carbon dioxide injection test operation is repeated to obtain a final carbon dioxide injection operation plan with minimal identified risk.

5. The method according to claim 1, wherein the monitoring of the carbon dioxide injection operation further comprises tuning the second simulation model based on the measured real-time data.

6. The method according to claim 1, wherein after the comparing of the real-time data with the first simulation model and the second simulation model, further comprises modifying the first simulation model and the second simulation model based on the real-time data.

7. The method according to claim 1, wherein the validating of the carbon dioxide operation plan further comprises applying a geomechanical model to the first simulation to the first simulation model and the second simulation model.

8. An article of manufacture configured to be read by a computing device, the article of manufacture configured with a list of instructions, the list of instructions configured to operate on the computing device, the list of instructions configured to perform a method comprising:
validating a carbon dioxide injection operation plan at an injection site, comprising:
creating a first simulation model to simulate flow from a wellhead to a downhole;
creating a second simulation model to simulate flow dynamics in a reservoir;
identifying risks from the first simulation model and the second simulation model; and
adjusting the carbon injection operation plan to mitigate the identified risk;
conducting a carbon dioxide injection test operation based on the carbon dioxide injection operation plan at the injection site;
monitoring the carbon dioxide injection test operation, comprising:
measuring real-time data from the wellhead and the downhole;
comparing the real-time data with the first simulation model; and
identifying risks from the comparison between the collected data and the first simulation model; and
adjusting the carbon dioxide injection operation plan to mitigate the identified risks.

9. The article of manufacture, according to claim 8, wherein the article of manufacture is in a form of a compact disk, a solid-state drive, a computer hard drive, a universal serial bus device, and a non-volatile memory arrangement.

10. A method for performing a carbon dioxide injectivity test, comprising:
validating a carbon dioxide injection operation plan at an injection site within a geological stratum, comprising:
creating a first simulation model of the injection site to simulate flow from a wellhead to a downhole environment;
creating a second simulation model to simulate flow dynamics in a reservoir in the geological stratum;
identifying risks associated with the first simulation model and the second simulation model; and
adjusting the carbon dioxide injection operation plan to mitigate the identified risks;
conducing a carbon dioxide injection test operation based on the carbon dioxide injection operation plan at the injection site within the geological stratum;
monitoring the carbon dioxide injection test operation, comprising:
measuring real-time data from the wellhead and the downhole environment;
storing the real-time data in a non-volatile memory;
comparing the real-time data with the first simulation model; and
identifying risks from the comparison between the collection data and the first simulation model; and
adjusting the carbon dioxide injection operation plan to mitigate the identified risks.

11. The method according to claim 10, further comprising interpreting data from the carbon dioxide injection test operation to infer key information.

12. The method according to claim 10, further comprising:
repeating the steps of validating the carbon dioxide injection operation plan to obtain a final carbon dioxide injection operation plan with a minimal identified risk.

13. The method according to claim 10, further comprising:
repeating the steps of monitoring the carbon dioxide injection test operation to obtain a final carbon dioxide injection operation plan with minimal identified risk.

14. The method according to claim 10, wherein the monitoring of the carbon dioxide injection operation further comprises:
tuning the second simulation model based on the measured real-time data.

15. The method according to claim 10, wherein after the comparing of the real-time data with the first simulation model and the second simulation model, further comprises modifying the first simulation model and the second simulation model based on the real-time data.

16. The method according to claim 10, wherein the validating of the carbon dioxide operation plan further comprises applying a geomechanical model to the first simulation to the first simulation model and the second simulation model.

17. The method according to claim 10, further comprising displaying the adjusted carbon dioxide injection operation plan.

18. The method according to claim 10, wherein at least one of the first simulation model and the second simulation model are prepared using field data of the geological stratum.

19. The method according to claim 10, further comprising stopping the carbon dioxide injection test operation when the identified risks meet a threshold.

20. The method according to claim 10, wherein historical data is used to create the first simulation model.
